(19) United States
(12) Patent Application Publication
(10) Pub. No.: US 2025/0046745 A1
(43) Pub. Date: Feb. 6, 2025

(54) SEMICONDUCTOR PACKAGE INCLUDING A PLURALITY OF SEMICONDUCTOR CHIPS

(71) Applicant: SAMSUNG ELECTRONICS CO., LTD., Suwon-si (KR)

(72) Inventor: Young Lyong KIM, Suwon-si (KR)

(21) Appl. No.: 18/595,216

(22) Filed: Mar. 4, 2024

(30) Foreign Application Priority Data
Aug. 2, 2023 (KR) 10-2023-0101247

(51) Int. Cl. H01L 23/00; H01L 23/367; H01L 23/498; H01L 25/065

(52) U.S. Cl. CPC H01L 24/29; H01L 23/3675; H01L 23/49816; H01L 24/05; H01L 25/0655; H01L 2224/05009; H01L 2224/05025; H01L 2224/29026; H01L 2224/2919; H01L 2924/1431; H01L 2924/1434; H01L 2924/15311; H01L 2924/182

(57) ABSTRACT

A semiconductor package includes first and second chips horizontally spaced apart from each other on a substrate. An under-fill layer is interposed between the substrate and the first and second chips. An upper mold layer is disposed on the substrate to cover side surfaces of the first and second chips. The second chip includes vertically-stacked sub-chips and a chip mold layer covering side surfaces of the sub-chips. The under-fill layer extends into a space between lower side surfaces of the chip mold layer and the first chip. The upper mold layer extends into a space between upper side surfaces of the chip mold layer and the first chip to cover an uppermost surface of the under-fill layer. The upper side surface of the chip mold layer is recessed inward from the lower side surface of the chip mold layer.

### CROSS-REFERENCE TO RELATED APPLICATIONS

This U.S. non-provisional patent application claims priority under 35 U.S.C. § 119 to Korean Patent Application No. 10-2023-0101247, filed on Aug. 2, 2023, in the Korean Intellectual Property Office, the entire contents of which are hereby incorporated by reference.

### TECHNICAL FIELD

The present disclosure relates to a semiconductor package, and in particular, to a semiconductor package, on which a plurality of semiconductor chips are mounted.

### DISCUSSION OF THE RELATED ART

A semiconductor package is configured to facilitate the incorporation of an integrated circuit (IC) chip as a component in an electronic product. In general, the semiconductor package includes a printed circuit board (PCB) and a semiconductor chip, which is mounted on the PCB and is electrically connected to the PCB by bonding wires or bumps. With the development of the electronics industry, small, light, and multifunctional electronic devices are being produced. Multi-chip package technologies have been developed for mounting a plurality of chips in a single semiconductor package. System-in-package technologies have been developed for providing chips of different kinds, which are mounted in a single semiconductor package to serve as a single system.

### SUMMARY

A semiconductor package includes a first semiconductor chip and a second semiconductor chip disposed on an upper substrate and horizontally spaced apart from each other. An upper under-fill layer is interposed between the upper substrate and the first semiconductor chip and is interposed between the upper substrate and the second semiconductor chip. An upper mold layer is disposed on the upper substrate and covers side surfaces of the first and second semiconductor chips. The second semiconductor chip includes sub-semiconductor chips stacked in a vertical direction perpendicular to an upper surface of the upper substrate and a chip mold layer covering side surfaces of the sub-semiconductor chips. The upper under-fill layer extends into a space between a lower side surface of the chip mold layer and a lower side surface of the first semiconductor chip. The upper mold layer extends into a space between an upper side surface of the chip mold layer and an upper side surface of the first semiconductor chip and covers the uppermost surface of the upper under-fill layer. The upper side surface of the chip mold layer is recessed from the lower side surface of the chip mold layer toward an inner portion of the chip mold layer.

A semiconductor package includes a first semiconductor chip and a second semiconductor chip disposed on an upper substrate and horizontally spaced apart from each other. An upper under-fill layer is interposed between the upper substrate and the first semiconductor chip and between the upper substrate and the second semiconductor chip. An upper mold layer is interposed between the first semiconductor chip and the second semiconductor chip. The second semiconductor chip includes at least one sub-semiconductor chip and a chip mold layer covering a side surface of the at least one sub-semiconductor chip. A lower side surface of the chip mold layer faces a lower side surface of the first semiconductor chip. An upper side surface of the chip mold layer faces an upper side surface of the first semiconductor chip. The upper side surface of the chip mold layer is recessed from the lower side surface of the chip mold layer toward an inner portion of the chip mold layer. The upper under-fill layer is extended into a space between the lower side surface of the chip mold layer and the lower side surface of the first semiconductor chip. The uppermost surface of the upper under-fill layer is located at a height that is lower than upper surfaces of the first and second semiconductor chips. The upper mold layer fills a space between the upper side surface of the chip mold layer and the upper side surface of the first semiconductor chip and covers the uppermost surface of the upper under-fill layer.

A method of fabricating a semiconductor package includes mounting a first semiconductor chip and a second semiconductor chip, which are horizontally spaced apart from each other, on an upper substrate. The second semiconductor chip includes at least one sub-semiconductor chip and a chip mold layer covering a side surface of the at least one sub-semiconductor chip. A side surface of the chip mold layer is partially recessed such that the chip mold layer has a lower side surface and an upper side surface recessed from the lower side surface toward an inner portion of the chip mold layer. An upper under-fill layer is formed. The upper under-fill layer is interposed between the upper substrate and the first semiconductor chip and between the upper substrate and the second semiconductor chip and is extended into a space between the lower side surface of the chip mold layer and a lower side surface of the first semiconductor chip. An upper mold layer is formed. The upper mold layer fills a space between the upper side surface of the chip mold layer and an upper side surface of the first semiconductor chip and covers the uppermost surface of the upper under-fill layer.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a plan view illustrating a semiconductor package according to an embodiment of the inventive concept;

FIG. 2 is a cross-sectional view taken along a line A-A′ of FIG. 1;

FIGS. 3, 5, 7, and 9 are plan views illustrating a method of fabricating a semiconductor package, according to an embodiment of the inventive concept;

FIGS. 4, 6, 8, and 10 are cross-sectional views taken along lines A-A′ of FIGS. 3, 5, 7, and 9, respectively;

FIG. 11 is a plan view illustrating a semiconductor package according to an embodiment of the inventive concept;

FIGS. 12A and 12B are cross-sectional views taken along a line A-A′ of FIG. 11;

FIG. 13 is a plan view illustrating a semiconductor package according to an embodiment of the inventive concept;

FIG. 14 is a cross-sectional view taken along a line B-B′ of FIG. 13;

FIGS. 15, 17, 19, and 21 are plan views illustrating a method of fabricating a semiconductor package, according to an embodiment of the inventive concept;

FIGS. 16, 18, 20, and 22 are cross-sectional views taken along lines B-B′ of FIGS. 15, 17, 19, and 21, respectively;

FIG. 23 is a plan view illustrating a semiconductor package according to an embodiment of the inventive concept; and

FIG. 24 is a cross-sectional view taken along a line B-B′ of FIG. 23.

### DETAILED DESCRIPTION

Example embodiments of the inventive concepts will now be described more fully with reference to the accompanying drawings.

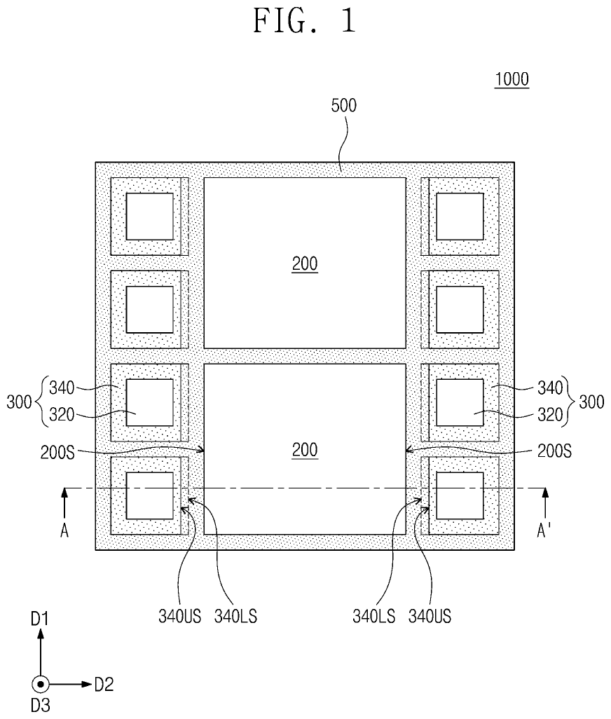

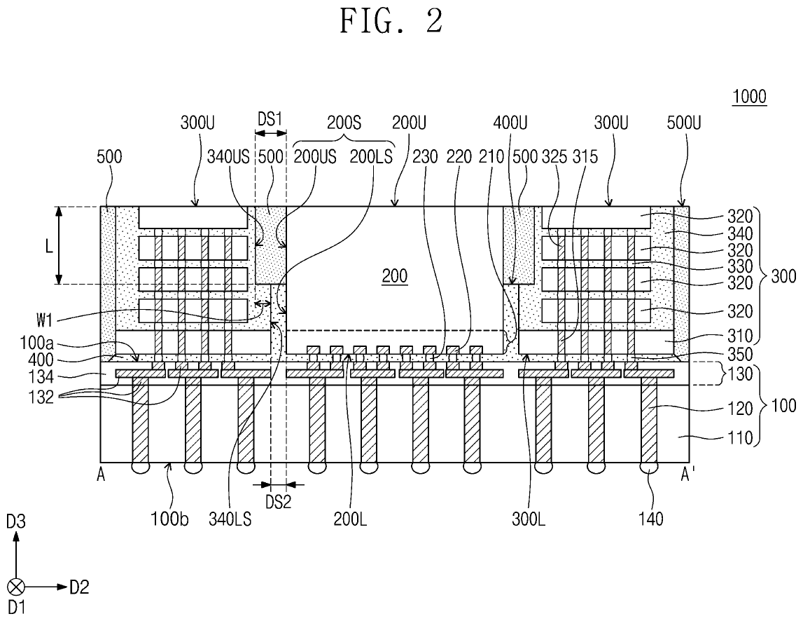

FIG. 1 is a plan view illustrating a semiconductor package according to an embodiment of the inventive concept. FIG. 2 is a cross-sectional view taken along a line A-A′ of FIG. 1. Referring to FIGS. 1 and 2, a semiconductor package 1000 may include an upper substrate 100. A first semiconductor chip 200 and a second semiconductor chip 300 are disposed on the upper substrate 100 and are horizontally spaced apart from each other. The upper substrate 100 may have a first surface 100a and a second surface 100b, which are opposite to each other, and the first and second semiconductor chips 200 and 300 may be mounted on the first surface 100a of the upper substrate 100.

In an embodiment, a plurality of first semiconductor chips 200 may be mounted on the first surface 100a of the upper substrate 100 and may be spaced apart from each other in a first direction D1 that is parallel to the first surface 100a of the upper substrate 100. A plurality of second semiconductor chips 300 may be mounted on the first surface 100a of the upper substrate 100 and may be disposed at both sides of each of the first semiconductor chips 200. The second semiconductor chips 300 may form first and second columns, where the second semiconductor chips 300 in the first column are spaced apart from each other in the first direction D1 at one side of each of the first semiconductor chips 200 and the second semiconductor chips 300 in the second column are spaced apart from each other in the first direction D1 at an opposite side of each of the first semiconductor chips 200. The second semiconductor chips 300 of the second column may be spaced apart from the second semiconductor chips 300 of the first column in a second direction D2, which is parallel to the first surface 100a of the upper substrate 100 and is not parallel to the first direction D1. The first semiconductor chips 200 may be disposed between the second semiconductor chips 300 of the first column and the second semiconductor chips 300 of the second column.

The upper substrate 100 may include a semiconductor substrate 110, a plurality of penetration electrodes 120 penetrating the semiconductor substrate 110, and an interconnection layer 130 disposed on the semiconductor substrate 110. The interconnection layer 130 may be adjacent to the first surface 100a of the upper substrate 100, and the semiconductor substrate 110 may be adjacent to the second surface 100b of the upper substrate 100.

In an embodiment, the semiconductor substrate 110 may be a silicon substrate. The penetration electrodes 120 in the semiconductor substrate 110 may be spaced apart from each other in a horizontal direction (e.g., the first or second direction D1 or D2). Each of the penetration electrodes 120 may be extended in a third direction D3 perpendicular to the first surface 100a of the upper substrate 100 and may penetrate the semiconductor substrate 110. The penetration electrodes 120 may include an electrically conductive and/or metal (e.g., copper). The interconnection layer 130 may include interconnection patterns 132 and an interconnection insulating layer 134 covering the interconnection patterns 132. The penetration electrodes 120 may be (e.g., electrically) connected to corresponding ones of the interconnection patterns 132. The interconnection patterns 132 may include an electrically conductive material (e.g., a metal), and the interconnection insulating layer 134 may include an electrically insulating material. In an embodiment, the upper substrate 100 may be an interposer substrate.

Connection terminals 140 may be disposed on the second surface 100b of the upper substrate 100. The penetration electrodes 120 may be (e.g., electrically) connected to the connection terminals 140. The connection terminals 140 may include a conductive material and may be solder balls, bumps, and/or pillars.

The first semiconductor chip 200 may have an upper surface 200U and a lower surface 200L, which are opposite to each other, and the lower surface 200L of the first semiconductor chip 200 may face the first surface 100a of the upper substrate 100. The first semiconductor chip 200 may include a circuit layer 210 and chip pads 220, disposed adjacent to the lower surface 200L of the first semiconductor chip 200. The circuit layer 210 may include integrated circuits, and the chip pads 220 may be electrically connected to the integrated circuits in the circuit layer 210. The chip pads 220 may include a conductive material (e.g., a metal).

First bumps 230 may be disposed on the lower surface 200L of the first semiconductor chip 200 and on the chip pads 220. The first bumps 230 may be (e.g., electrically) connected to the chip pads 220. The first bumps 230 may be disposed between the lower surface 200L of the first semiconductor chip 200 and the first surface 100a of the upper substrate 100 and may be (e.g., electrically) connected to corresponding ones of the interconnection patterns 132 in the interconnection layer 130. The first semiconductor chip 200 may be electrically connected to the upper substrate 100 through the chip pads 220, the first bumps 230, and the corresponding interconnection patterns 132. The first bumps 230 may be formed of or may otherwise include at least one electrically conductive material and may be solder balls, bumps, and/or pillars.

The second semiconductor chip 300 may have an upper surface 300U and a lower surface 300L, which are opposite to each other, and here, the lower surface 300L of the second semiconductor chip 300 may face the first surface 100a of the upper substrate 100. The second semiconductor chip 300 may include a buffer semiconductor chip 310 and a plurality of sub-semiconductor chips 320, which are stacked on the buffer semiconductor chip 310 in the third direction D3. The lower surface 300L of the second semiconductor chip 300 may correspond to a lower surface of the buffer semiconductor chip 310, and the upper surface 300U of the second semiconductor chip 300 may correspond to an upper surface of the uppermost one of the sub-semiconductor chips 320. In the present specification, the third direction D3 may be referred to as a vertical direction.

The buffer semiconductor chip 310 may include buffer penetration electrodes 315, which penetrate the buffer semiconductor chip 310 in the third direction D3. The buffer penetration electrodes 315 may include an electrically conductive material (e.g., a metal). Each of the sub-semiconductor chips 320 may include sub-penetration electrodes 325, which penetrate each of the sub-semiconductor chips 320 in the third direction D3. In an embodiment, the uppermost sub-semiconductor chip 320 might not include the sub-penetration electrodes 325. The sub-penetration electrodes 325 may include a conductive material (e.g., a metal).

The second semiconductor chip 300 may further include sub-bumps 330, which are disposed between the sub-semiconductor chips 320 and between the lowermost one of the sub-semiconductor chips 320 and the buffer semiconductor chip 310. The sub-bumps 330 may be (e.g., electrically) connected to the sub-penetration electrodes 325 and the buffer penetration electrodes 315. The buffer semiconductor chip 310 and the sub-semiconductor chips 320 may be electrically connected to each other through the sub-penetration electrodes 325, the buffer penetration electrodes 315, and the sub-bumps 330. The sub-bumps 330 may include an electrically conductive material and may be solder balls, bumps, and/or pillars.

The second semiconductor chip 300 may further include a chip mold layer 340, which is disposed on the buffer semiconductor chip 310 and may cover side surfaces of the sub-semiconductor chips 320. The chip mold layer 340 may be extended into regions between the sub-semiconductor chips 320 and between the lowermost sub-semiconductor chip 320 and the buffer semiconductor chip 310 and may cover the sub-bumps 330. The chip mold layer 340 may include an epoxy molding compound.

Second bumps 350 may be disposed on the lower surface 300L of the second semiconductor chip 300 and may be (e.g., electrically) connected to the buffer penetration electrodes 315. The second bumps 350 may be disposed between the lower surface 300L of the second semiconductor chip 300 and the first surface 100a of the upper substrate 100 and may be (e.g., electrically) connected to corresponding ones of the interconnection patterns 132 in the interconnection layer 130. The second semiconductor chip 300 may be electrically connected to the upper substrate 100 through the second bumps 350 and the corresponding interconnection patterns 132. The second bumps 350 may be formed of or may otherwise include at least one electrically conductive material and may be solder balls, bumps, and/or pillars.

The first and second semiconductor chips 200 and 300 may be two different chips, which are selected from a memory chip, a logic chip, an application processor (AP) chip, and a system-on-chip (SOC). As an example, the first semiconductor chip 200 may be one of a logic chip, an application processor (AP) chip, and a system-on-chip (SOC), and the second semiconductor chip 300 may be a memory chip. As an example, the buffer semiconductor chip 310 may include a logic circuit, a memory circuit, or combinations thereof, and the sub-semiconductor chips 320 may be memory chips of the same kind. For example, the second semiconductor chip 300 may be a high bandwidth memory (HBM) chip, in which memory chips of the same kind are stacked.

A side surface 340LS or 340US of the chip mold layer 340 of the second semiconductor chip 300 may face a side surface 200S of the first semiconductor chip 200. The side surface 340LS or 340US of the chip mold layer 340 may have a staircase structure. An upper side surface 340US of the chip mold layer 340 may be recessed from a lower side surface 340LS of the chip mold layer 340 toward an inner portion of the chip mold layer 340. The side surface 200S of the first semiconductor chip 200 may include an upper side surface 200US facing the upper side surface 340US of the chip mold layer 340 and a lower side surface 200LS facing the lower side surface 340LS of the chip mold layer 340. The upper side surface 200US of the first semiconductor chip 200 and the lower side surface 200LS of the first semiconductor chip 200 may be aligned with each other in the third direction D3. The upper side surface 200US of the first semiconductor chip 200 may be coplanar with the lower side surface 200LS of the first semiconductor chip 200. The side surface 200S of the first semiconductor chip 200 may be perpendicular to the first surface 100a of the upper substrate 100.

A first distance DS1 between the upper side surface 340US of the chip mold layer 340 and the upper side surface 200US of the first semiconductor chip 200 may be larger than a second distance DS2 between the lower side surface 340LS of the chip mold layer 340 and the lower side surface 200LS of the first semiconductor chip 200. In an embodiment, the second distance DS2 may range from 30 μm to 90 μm. A length L of the upper side surface 340US of the chip mold layer 340 in the third direction D3 may range from 50 μm to 600 μm. The upper side surface 340US of the chip mold layer 340 may be recessed from the lower side surface 340LS of the chip mold layer 340 by a first width W1, where the first width W1 is measured in a direction (e.g., the second direction D2) parallel to the first surface 100a of the upper substrate 100. In an embodiment, the first width W1 may be larger than or equal to 50 μm.

An upper under-fill layer 400 may be interposed between the upper substrate 100 and the first semiconductor chip 200 and between the upper substrate 100 and the second semiconductor chip 300. The upper under-fill layer 400 may fill a space between the first bumps 230 and a space between the second bumps 350. The upper under-fill layer 400 may be extended into a space between the first and second semiconductor chips 200 and 300. The upper under-fill layer 400 may be extended into a space between the lower side surface 340LS of the chip mold layer 340 and the lower side surface 200LS of the first semiconductor chip 200 and may expose the upper side surface 340US of the chip mold layer 340 and the upper side surface 200US of the first semiconductor chip 200. The uppermost surface 400U of the upper under-fill layer 400 may be located at a height that is lower than the upper surface 200U of the first semiconductor chip 200 and the upper surface 300U of the second semiconductor chip 300. In the present specification, the height may be a distance measured from the first surface 100a of the upper substrate 100 in the third direction D3.

An upper mold layer 500 may be disposed on the upper substrate 100 and may cover side surfaces of the first and second semiconductor chips 200 and 300. The upper mold layer 500 may be extended into a space between the upper side surface 340US of the chip mold layer 340 and the upper side surface 200US of the first semiconductor chip 200 and may cover the uppermost surface 400U of the upper under-fill layer 400. The upper mold layer 500 may fill a space between the upper side surface 340US of the chip mold layer 340 and the upper side surface 200US of the first semiconductor chip 200 and may be in direct contact with the uppermost surface 400U of the upper under-fill layer 400. An upper surface 500U of the upper mold layer 500 may be located at the same height as the upper surface 200U of the first semiconductor chip 200 and the upper surface 300U of the second semiconductor chip 300. The upper surface 500U of the upper mold layer 500 may be coplanar with the upper surface 200U of the first semiconductor chip 200 and the upper surface 300U of the second semiconductor chip 300.

The upper under-fill layer 400 may include an insulating polymer material (e.g., an epoxy resin). The upper mold layer 500 may include an epoxy molding compound (EMC). A thermal expansion coefficient of the upper mold layer 500 may be smaller than a thermal expansion coefficient of the upper under-fill layer 400. As an example, the thermal expansion coefficient of the upper mold layer 500 may range from 7 ppm to 10 ppm, and a thermal expansion coefficient of the upper under-fill layer 400 may range from 24 ppm to 30 ppm. Each of the upper mold layer 500 and the upper under-fill layer 400 may include a filler, and in an embodiment, the filler may include silica (silicon dioxide, SiO₂). An amount of the filler contained in the upper mold layer 500 may be greater than an amount of the filler contained in the upper under-fill layer 400. In an embodiment, the amount of the filler contained in the upper mold layer 500 may range from about 80 wt % to 99 wt %, the amount of the filler contained in the upper under-fill layer 400 may range from about 50 wt % to 60 wt %. A size (e.g., volume) of the filler in the upper mold layer 500 may be larger than a size (e.g., volume) of the filler in the upper under-fill layer 400. In an embodiment, the size (e.g., volume) of the filler in the upper mold layer 500 may be larger than or equal to 1.5 times the size (e.g., volume) of the filler in the upper under-fill layer 400.

In the case where the distance between the first and second semiconductor chips 200 and 300 is relatively small, the upper under-fill layer 400 may be extended into a space between the first and second semiconductor chips 200 and 300 by the capillary force and may be extended to the same height as the upper surface 200U of the first semiconductor chip 200 and the upper surface 300U of the second semiconductor chip 300. Thus, the upper under-fill layer 400 may fill a space between the first and second semiconductor chips 200 and 300 and may be exposed to the outside of the semiconductor package 1000. In this case, a crack may occur between the first and second semiconductor chips 200 and 300, because the upper under-fill layer 400 has a relatively great thermal expansion coefficient, and such a crack may propagate into the semiconductor package 1000. In addition, a warpage failure may occur in the semiconductor package 1000.

By contrast, according to an embodiment of the inventive concept, a portion of the chip mold layer 340 of the second semiconductor chip 300 may be removed from a region between the first and second semiconductor chips 200 and 300. Thus, the upper side surface 340US of the chip mold layer 340 may be recessed from the lower side surface 340LS of the chip mold layer 340 toward an inner portion of the chip mold layer 340, and the side surface 340LS or 340US of the chip mold layer 340 may have a staircase structure. The first distance DS1 between the upper side surface 340US of the chip mold layer 340 and the upper side surface 200US of the first semiconductor chip 200 may be larger than the second distance DS2 between the lower side surface 340LS of the chip mold layer 340 and the lower side surface 200LS of the first semiconductor chip 200. In this case, the upper under-fill layer 400 may be extended into the relatively narrow space between the lower side surface 340LS of the chip mold layer 340 and the lower side surface 200LS of the first semiconductor chip 200 by the capillary force and might not be extended into the relatively wide space between the upper side surface 340US of the chip mold layer 340 and the upper side surface 200US of the first semiconductor chip 200. The uppermost surface 400U of the upper under-fill layer 400 may be located at a height that is lower than the upper surface 200U of the first semiconductor chip 200 and the upper surface 300U of the second semiconductor chip 300. The upper mold layer 500 may fill the space between the upper side surface 340US of the chip mold layer 340 and the upper side surface 200US of the first semiconductor chip 200 and to cover the uppermost surface 400U of the upper under-fill layer 400. The upper under-fill layer 400 might not be exposed to the outside of the semiconductor package 1000, because it is covered with the upper mold layer 500. Since the upper mold layer 500 has a thermal expansion coefficient that is less than the upper under-fill layer 400, a crack failure between the first and second semiconductor chips 200 and 300 may be reduced, and a warpage failure of the semiconductor package 1000 may also be reduced.

Since the crack and warpage issues are suppressed, it may be possible to realize a highly-reliable semiconductor package.

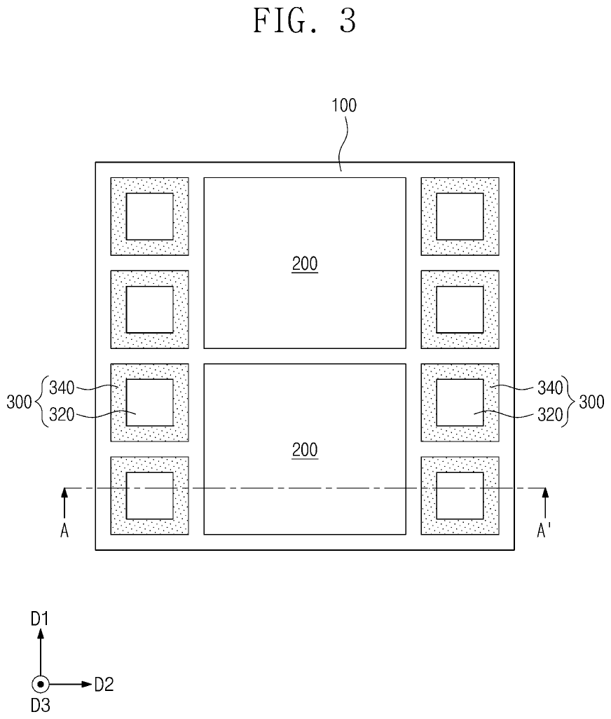

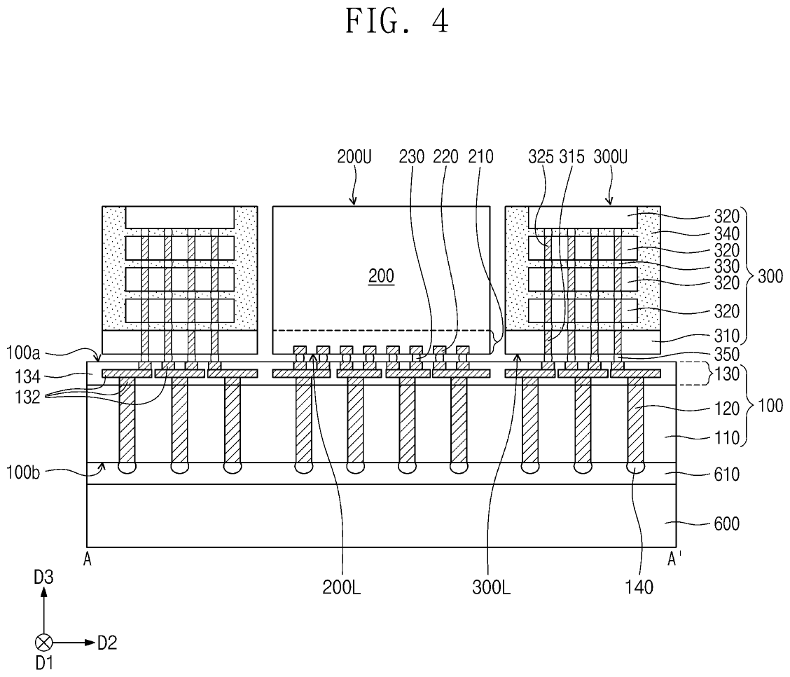

FIGS. 3, 5, 7, and 9 are plan views illustrating a method of fabricating a semiconductor package, according to an embodiment of the inventive concept. FIGS. 4, 6, 8, and 10 are cross-sectional views taken along lines A-A′ of FIGS. 3, 5, 7, and 9, respectively. For concise description, an element described with reference to FIGS. 1 and 2 may be identified by the same reference number and to the extent that an element is not described in detail with respect to this figure, it may be understood that the element is at least similar to a corresponding element that has been described elsewhere within the present disclosure.

Referring to FIGS. 3 and 4, an upper substrate 100 may be disposed on a carrier substrate 600, and an adhesion layer 610 may be disposed between the carrier substrate 600 and the upper substrate 100. The carrier substrate 600 may be, for example, a glass substrate. The adhesion layer 610 may include an adhesive material.

The upper substrate 100 may have a first surface 100a and a second surface 100b, which are opposite to each other. The upper substrate 100 may include a semiconductor substrate 110 adjacent to the second surface 100b, an interconnection layer 130 adjacent to the first surface 100a, and a plurality of penetration electrodes 120 penetrating the semiconductor substrate 110. The interconnection layer 130 may include interconnection patterns 132 and an interconnection insulating layer 134 covering the interconnection patterns 132, and the penetration electrodes 120 may penetrate the semiconductor substrate 110 and may be (e.g., electrically) connected to corresponding ones of the interconnection patterns 132. The upper substrate 100 may be, for example, an interposer substrate. Connection terminals 140 may be disposed on the second surface 100b of the upper substrate 100.

The adhesion layer 610 may be disposed between the second surface 100b of the upper substrate 100 and the carrier substrate 600. The connection terminals 140 may be disposed in the adhesion layer 610. The upper substrate 100 may be attached to the carrier substrate 600 using the adhesion layer 610.

A first semiconductor chip 200 and a second semiconductor chip 300 may be mounted on the first surface 100a of the upper substrate 100.

The first semiconductor chip 200 may have an upper surface 200U and a lower surface 200L, which are opposite to each other, and the lower surface 200L of the first semiconductor chip 200 may face the first surface 100a of the upper substrate 100. The first semiconductor chip 200 may include a circuit layer 210 and chip pads 220, which are disposed adjacent to the lower surface 200L of the first semiconductor chip 200. First bumps 230 may be disposed on the lower surface 200L of the first semiconductor chip 200 and on the chip pads 220. The first bumps 230 may be (e.g., electrically) connected to corresponding ones of the interconnection patterns 132 in the interconnection layer 130 of the upper substrate 100. The first semiconductor chip 200 may be electrically connected to the upper substrate 100 through the chip pads 220, the first bumps 230, and the corresponding interconnection patterns 132.

The second semiconductor chip 300 may have an upper surface 300U and a lower surface 300L, which are opposite to each other, and the lower surface 300L of the second semiconductor chip 300 may face the first surface 100a of the upper substrate 100. The second semiconductor chip 300 may include a buffer semiconductor chip 310 and a plurality of sub-semiconductor chips 320, which are stacked on the buffer semiconductor chip 310 in the third direction D3. The buffer semiconductor chip 310 may include buffer penetration electrodes 315, which penetrate the buffer semiconductor chip 310 in the third direction D3. Each of the sub-semiconductor chips 320 may include sub-penetration electrodes 325, which penetrate each of the sub-semiconductor chips 320 in the third direction D3. The second semiconductor chip 300 may further include sub-bumps 330, which are disposed between the sub-semiconductor chips 320 and between the lowermost one of the sub-semiconductor chips 320 and the buffer semiconductor chip 310. The sub-bumps 330 may be (e.g., electrically) connected to the sub-penetration electrodes 325 and the buffer penetration electrodes 315. The buffer semiconductor chip 310 and the sub-semiconductor chips 320 may be electrically connected to each other through the sub-penetration electrodes 325, the buffer penetration electrodes 315, and the sub-bumps 330. The second semiconductor chip 300 may be disposed on the buffer semiconductor chip 310 and may further include a chip mold layer 340 covering side surfaces of the sub-semiconductor chips 320.

Second bumps 350 may be disposed on the lower surface 300L of the second semiconductor chip 300 and may be (e.g., electrically) connected to the buffer penetration electrodes 315. The second bumps 350 may be (e.g., electrically) connected to corresponding ones of the interconnection patterns 132 in the interconnection layer 130 of the upper substrate 100. The second semiconductor chip 300 may be electrically connected to the upper substrate 100 through the second bumps 350 and the corresponding interconnection patterns 132.

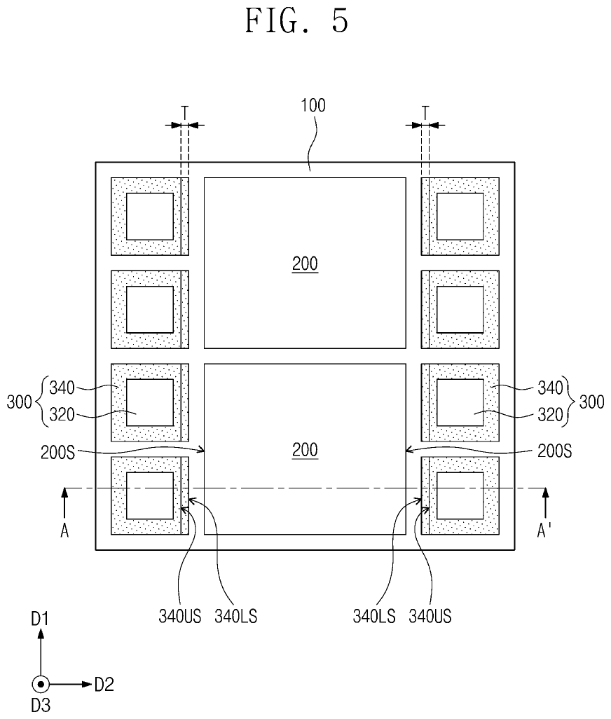

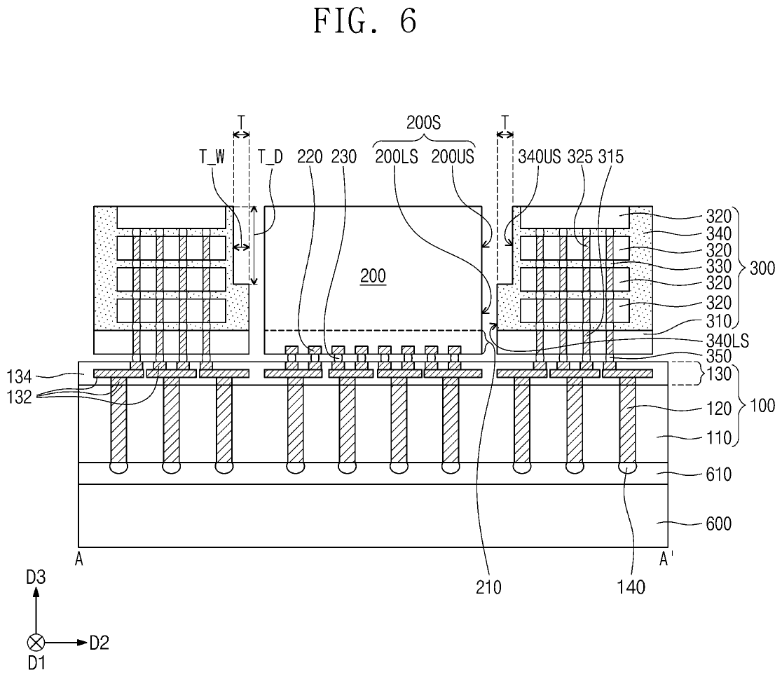

Referring to FIGS. 5 and 6, a portion of the chip mold layer 340 of the second semiconductor chip 300 may be removed from a region between the first and second semiconductor chips 200 and 300. The partial removal of the chip mold layer 340 may be performed using, for example, a laser process. As a result of the partial removal of the chip mold layer 340, a trench T may be formed in the chip mold layer 340. The trench T may penetrate a portion of the chip mold layer 340 and to extend in the first direction D1.

The upper side surface 340US and the lower side surface 340LS of the chip mold layer 340 may be defined by the trench T. The upper side surface 340US of the chip mold layer 340 may be recessed from the lower side surface 340LS of the chip mold layer 340 toward an inner portion of the chip mold layer 340, and thus, the side surface 340LS or 340US of the chip mold layer 340 may have a staircase structure. The side surface 200S of the first semiconductor chip 200 may include the upper side surface 200US facing the upper side surface 340US of the chip mold layer 340 and the lower side surface 200LS facing the lower side surface 340LS of the chip mold layer 340. The upper side surface 200US of the first semiconductor chip 200 and the lower side surface 200LS of the first semiconductor chip 200 may be aligned with each other in the third direction D3.

In an embodiment, a depth T_D of the trench T in the third direction D3 may range from 50 μm to 600 μm. The depth T_D of the trench T may correspond to a length of the upper side surface 340US of the chip mold layer 340 in the third direction D3. A width T_W of the trench T may be larger than or equal to 50 μm. The width T_W of the trench T may be measured in a direction (e.g., the second direction D2) parallel to the first surface 100a of the upper substrate 100. The upper side surface 340US of the chip mold layer 340 may be recessed from the lower side surface 340LS of the chip mold layer 340 by the width T_W of the trench T.

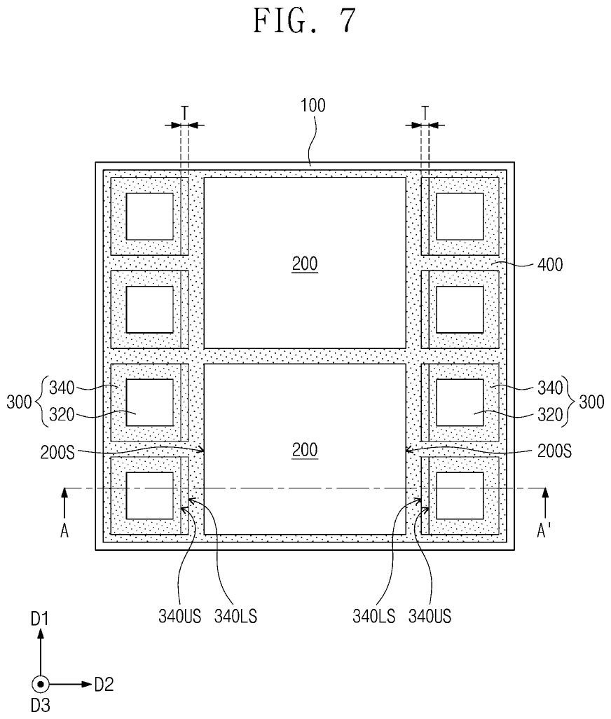

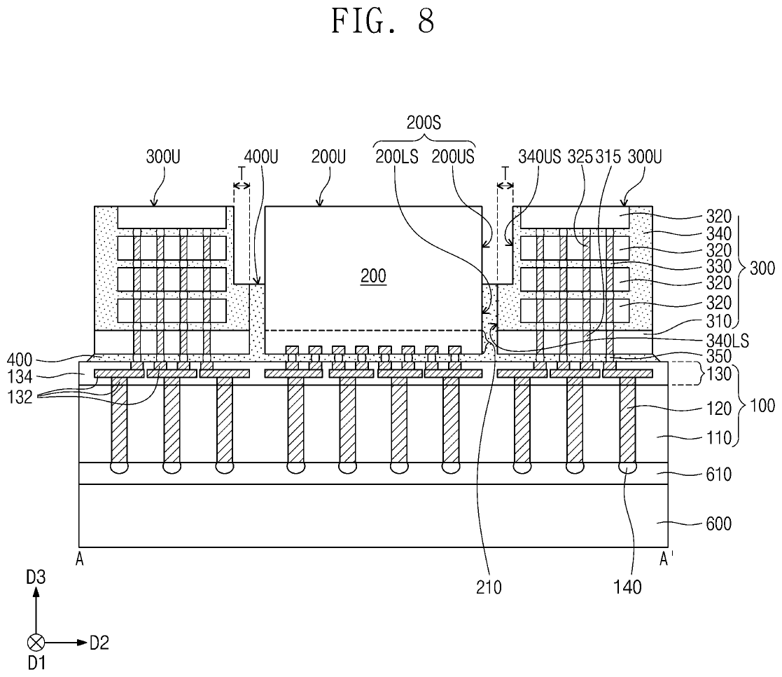

Referring to FIGS. 7 and 8, an upper under-fill layer 400 may be formed between the upper substrate 100 and the first semiconductor chip 200 and between the upper substrate 100 and the second semiconductor chip 300. The upper under-fill layer 400 may fill a space between the first bumps 230 and a space between the second bumps 350. The upper under-fill layer 400 may be extended into a space between the lower side surface 340LS of the chip mold layer 340 and the lower side surface 200LS of the first semiconductor chip 200 by the capillary force.

Owing to the trench T, a space between the upper side surface 340US of the chip mold layer 340 and the upper side surface 200US of the first semiconductor chip 200 may be wider than the space between the lower side surface 340LS of the chip mold layer 340 and the lower side surface 200LS of the first semiconductor chip 200. Thus, the upper under-fill layer 400 might not be extended into the space between the upper side surface 340US of the chip mold layer 340 and the upper side surface 200US of the first semiconductor chip 200. The uppermost surface 400U of the upper under-fill layer 400 may be located at a height that is lower than the upper surface 200U of the first semiconductor chip 200 and the upper surface 300U of the second semiconductor chip 300.

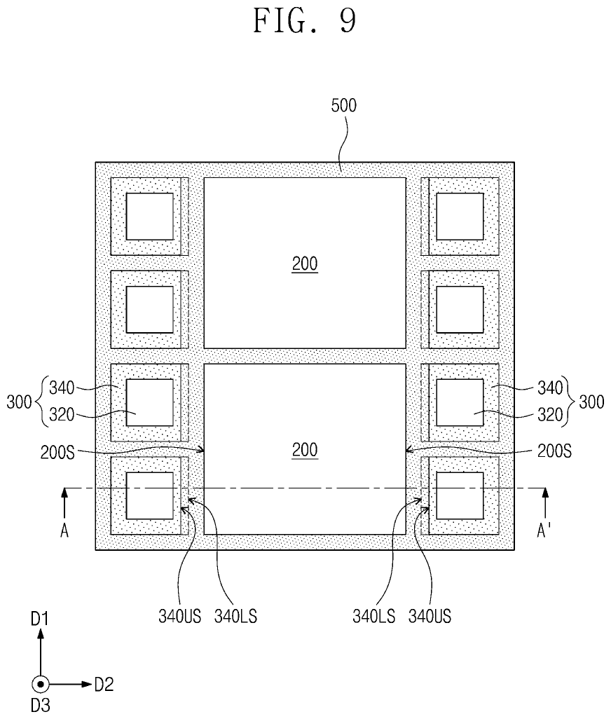

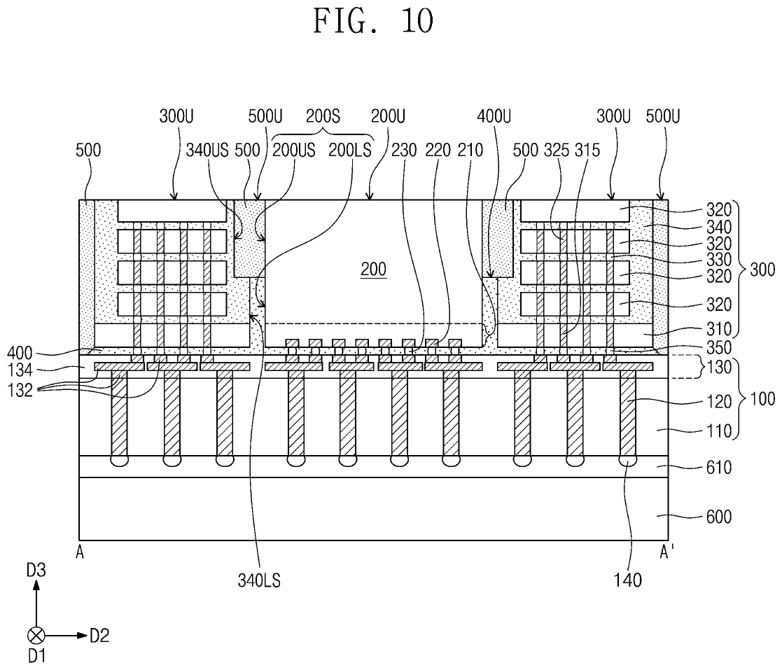

Referring to FIGS. 9 and 10, an upper mold layer 500 may be formed on the upper substrate 100 to cover side surfaces of the first and second semiconductor chips 200 and 300. The upper mold layer 500 may be extended into the space between the upper side surface 340US of the chip mold layer 340 and the upper side surface 200US of the first semiconductor chip 200 and may cover the uppermost surface 400U of the upper under-fill layer 400. The formation of the upper mold layer 500 may include forming the upper mold layer 500 on the upper substrate 100 to cover the first and second semiconductor chips 200 and 300 and grinding the upper mold layer 500 to expose the upper surface 200U of the first semiconductor chip 200 and the upper surface 300U of the second semiconductor chip 300. As a result of the grinding process, the upper surface 500U of the upper mold layer 500 may be located at the same height as the upper surface 200U of the first semiconductor chip 200 and the upper surface 300U of the second semiconductor chip 300.

Referring back to FIGS. 1 and 2, the carrier substrate 600 and the adhesion layer 610 may be removed from the upper substrate 100 to expose the connection terminals 140. Thus, the semiconductor package 1000, according to an embodiment of the inventive concept, may be formed.

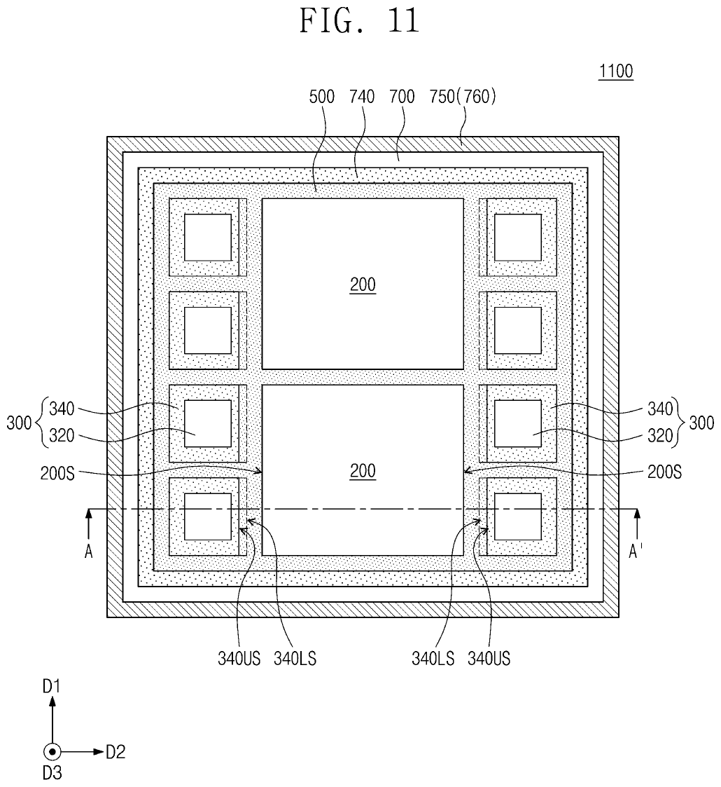

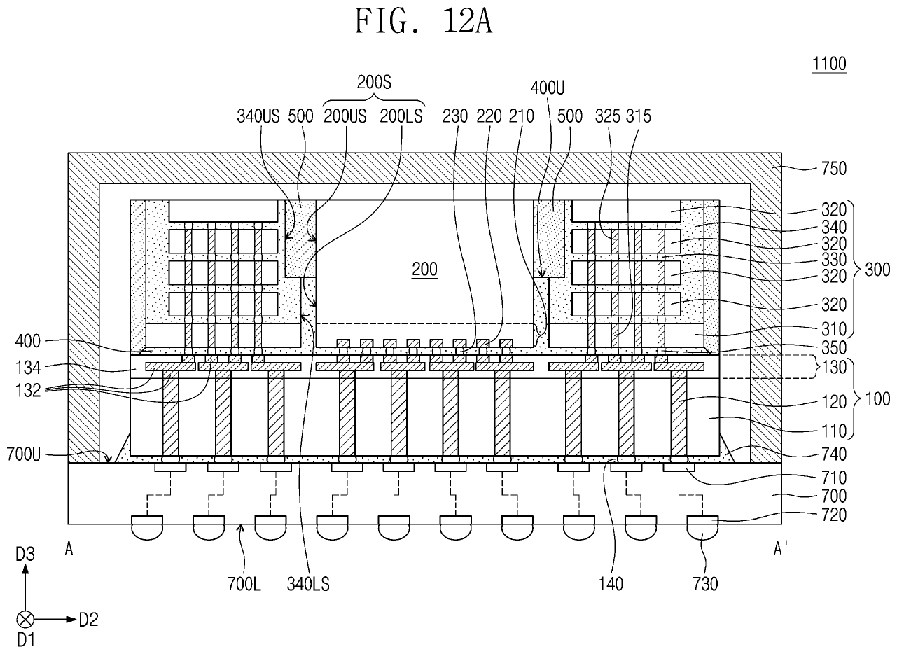

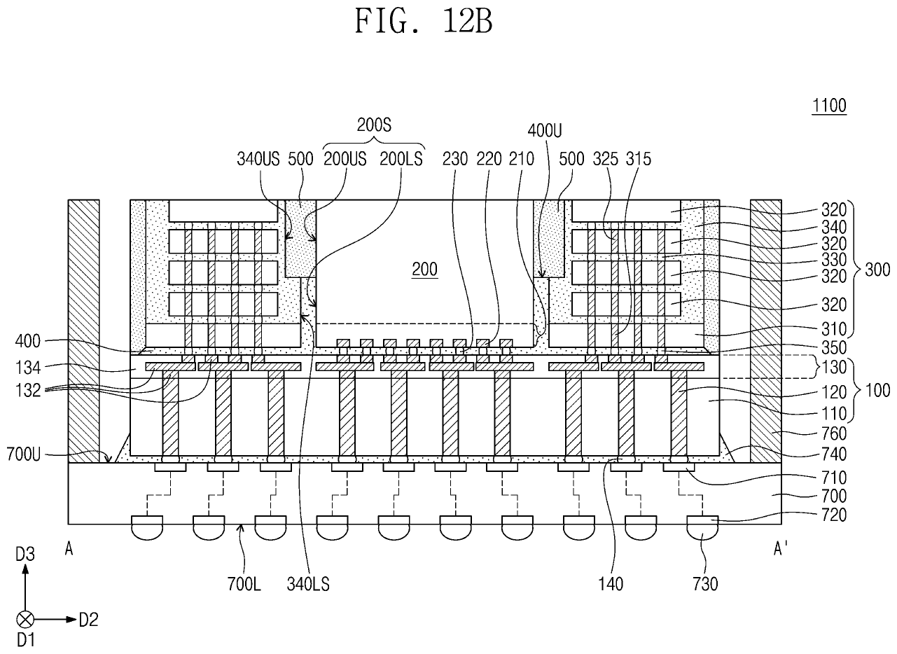

FIG. 11 is a plan view illustrating a semiconductor package according to an embodiment of the inventive concept. FIGS. 12A and 12B are cross-sectional views taken along a line A-A′ of FIG. 11. For concise description, features different from the semiconductor package previously described with reference to FIGS. 1 and 2 will be mainly described below and to the extent that an element is not described in detail with respect to this figure, it may be understood that the element is at least similar to a corresponding element that has been described elsewhere within the present disclosure.

Referring to FIGS. 11, 12A, and 12B, a semiconductor package 1100 may include a lower substrate 700, an upper substrate 100 on the lower substrate 700, and a first semiconductor chip 200 and a second semiconductor chip 300, which are mounted on the upper substrate 100.

The lower substrate 700 may include first substrate pads 710, which are adjacent to an upper surface 700U of the lower substrate 700, and second substrate pads 720, which are adjacent to a lower surface 700L of the lower substrate 700. The first and second substrate pads 710 and 720 may include a conductive material. The first substrate pads 710 may be electrically connected to the second substrate pads 720 through internal wires in the lower substrate 700. In an embodiment, the lower substrate 700 may be a printed circuit board (PCB). Outer terminals 730 may be disposed on the lower surface 700L of the lower substrate 700 and may be connected to the second substrate pads 720, respectively.

The upper substrate 100 and the first and second semiconductor chips 200 and 300 may have substantially the same features as the upper substrate 100 and the first and second semiconductor chips 200 and 300 described with reference to FIGS. 1 and 2.

Connection terminals 140 may be disposed between the upper substrate 100 and the lower substrate 700 and may be connected (e.g., electrically) to the first substrate pads 710 of the lower substrate 700, respectively. The connection terminals 140 may have substantially the same features as the connection terminals 140 described with reference to FIGS. 1 and 2. The upper substrate 100 may be electrically connected to the lower substrate 700 through the connection terminals 140.

A lower under-fill layer 740 may be interposed between the upper substrate 100 and the lower substrate 700 to fill a space between the connection terminals 140. The lower under-fill layer 740 may include an electrically insulating polymer material (e.g., an epoxy resin).

First bumps 230 may be disposed between the first semiconductor chip 200 and the upper substrate 100, and the first semiconductor chip 200 may be electrically connected to the upper substrate 100 through the first bumps 230. Second bumps 350 may be disposed between the second semiconductor chip 300 and the upper substrate 100, and the second semiconductor chip 300 may be electrically connected to the upper substrate 100 through the second bumps 350. The first bumps 230 and the second bumps 350 may have substantially the same features as the first bumps 230 and the second bumps 350 described with reference to FIGS. 1 and 2.

An upper under-fill layer 400 may be interposed between the upper substrate 100 and the first semiconductor chip 200 and between the upper substrate 100 and the second semiconductor chip 300 and may be extended into a space between the first and second semiconductor chips 200 and 300. The upper under-fill layer 400 may be extended into a space between the lower side surface 340LS of the chip mold layer 340 of the second semiconductor chip 300 and the lower side surface 200LS of the first semiconductor chip 200. An upper mold layer 500 may be disposed on the upper substrate 100 and may cover side surfaces of the first and second semiconductor chips 200 and 300. The upper mold layer 500 may be extended into a space between the upper side surface 340US of the chip mold layer 340 of the second semiconductor chip 300 and the upper side surface 200US of the first semiconductor chip 200 and may cover the uppermost surface 400U of the upper under-fill layer 400. The upper under-fill layer 400 and the upper mold layer 500 may have substantially the same features as the upper under-fill layer 400 and the upper mold layer 500 described with reference to FIGS. 1 and 2.

In an embodiment, the semiconductor package 1100 may further include a heat-dissipation structure 750 disposed on the lower substrate 700, as shown in FIGS. 11 and 12A. The heat-dissipation structure 750 may be disposed on the upper surface 700U of the lower substrate 700, and the semiconductor package 1000 described with reference to FIGS. 1 and 2 may be placed inside the heat-dissipation structure 750. The heat-dissipation structure 750 may include at least one of thermally conductive materials. The thermally conductive materials may include metals (e.g., copper and/or aluminum, and so forth) or carbon-containing materials (e.g., graphene, graphite, and/or carbon nanotube, and so forth). As an example, the heat-dissipation structure 750 may include one or more metal layers. As another example, the heat-dissipation structure 750 may include a heat sink or a heat pipe. As still other example. The heat-dissipation structure 750 may have a water cooling structure.

In an embodiment, the semiconductor package 1100 may further include a stiffener 760 disposed on the lower substrate 700, as shown in FIGS. 11 and 12B. The stiffener 760 may be disposed on the upper surface 700U of the lower substrate 700, and the semiconductor package 1000 described with reference to FIGS. 1 and 2 may be placed inside the stiffener 760. The stiffener 760 may include at least one metal.

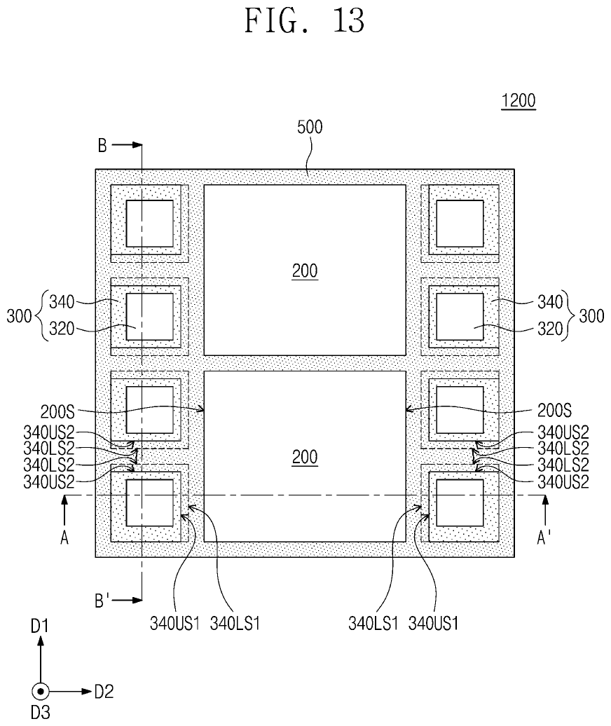

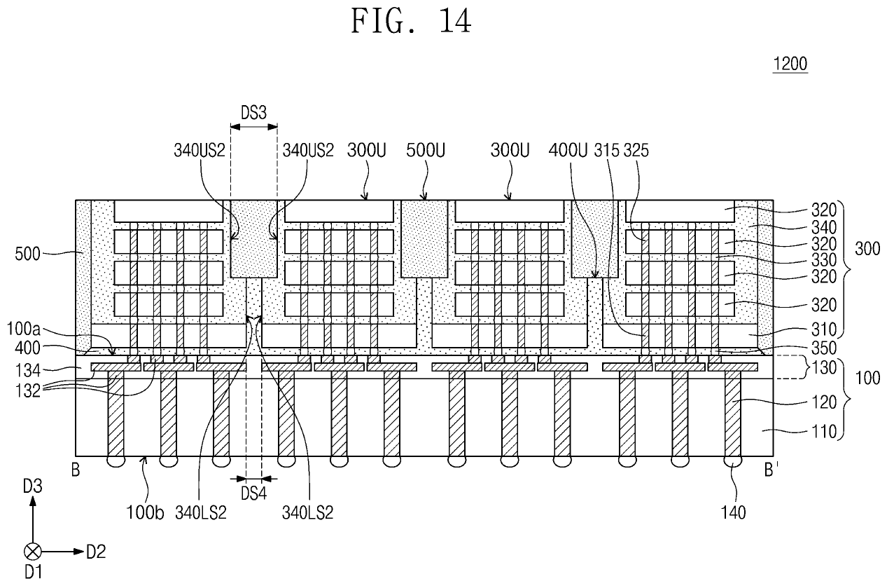

FIG. 13 is a plan view illustrating a semiconductor package according to an embodiment of the inventive concept. FIG. 14 is a cross-sectional view taken along a line B-B′ of FIG. 13. The sectional view taken along a line A-A′ of FIG. 13 may be the same as FIG. 2. For concise description, features different from the semiconductor package previously described with reference to FIGS. 1 and 2 will be mainly described below and to the extent that an element is not described in detail with respect to this figure, it may be understood that the element is at least similar to a corresponding element that has been described elsewhere within the present disclosure.

Referring to FIGS. 13 and 14, a semiconductor package 1200 may include an upper substrate 100 and a first semiconductor chip 200 and a second semiconductor chip 300, which are disposed on the upper substrate 100 and are horizontally spaced apart from each other. In an embodiment, a plurality of first semiconductor chips 200 may be mounted on the first surface 100a of the upper substrate 100 and may be spaced apart from each other in the first direction D1. A plurality of second semiconductor chips 300 may be mounted on the first surface 100a of the upper substrate 100 and may be disposed at both sides of each of the first semiconductor chips 200. The second semiconductor chips 300 may form first and second columns, where the second semiconductor chips 300 in the first column are spaced apart from each other in the first direction D1 at one side of each of the first semiconductor chips 200 and the second semiconductor chips 300 in the second column are spaced apart from each other in the first direction D1 at an opposite side of each of the first semiconductor chips 200.

The second semiconductor chips 300 may include a pair of second semiconductor chips 300, which are most adjacent to each other in the first direction D1. Each of the paired second semiconductor chips 300 may include a buffer semiconductor chip 310 and a plurality of sub-semiconductor chips 320, which are stacked on the buffer semiconductor chip 310 in the third direction D3. The buffer semiconductor chip 310 may include buffer penetration electrodes 315, which penetrate the buffer semiconductor chip 310 in the third direction D3, and each of the sub-semiconductor chips 320 may include sub-penetration electrodes 325, which respectively penetrate the sub-semiconductor chips 320 in the third direction D3. In an embodiment, the uppermost sub-semiconductor chip 320 might not include the sub-penetration electrodes 325.

Each of the paired second semiconductor chips 300 may further include sub-bumps 330, which are disposed between the sub-semiconductor chips 320 and between the lowermost one of the sub-semiconductor chips 320 and the buffer semiconductor chip 310. The sub-bumps 330 may be (e.g., electrically) connected to the sub-penetration electrodes 325 and the buffer penetration electrodes 315. Each of the paired second semiconductor chips 300 may be disposed on the buffer semiconductor chip 310 and may further include a chip mold layer 340 covering side surfaces of the sub-semiconductor chips 320.

Referring to FIGS. 13 and 2, the chip mold layer 340 of each of the paired second semiconductor chips 300 may have a first side surface 340LS1 or 340US1 facing the side surface 200S of the first semiconductor chip 200. The first side surface 340LS1 or 340US1 of the chip mold layer 340 may correspond to the side surfaces 340LS or 340US of the chip mold layer 340 described with reference to FIG. 2. The first side surface 340LS1 or 340US1 of the chip mold layer 340 may have a staircase structure. The first upper side surface 340US1 of the chip mold layer 340 may be recessed from the first lower side surface 340LS1 of the chip mold layer 340 toward an inner portion of the chip mold layer 340. The first upper side surface 340US1 and the first lower side surface 340LS1 of the chip mold layer 340 may correspond to the upper side surface 340US and the lower side surface 340LS of the chip mold layer 340 described with reference to FIG. 2. Referring back to FIGS. 13 and 14, the chip mold layer 340 of each of the paired second semiconductor chips 300 may have the second side surfaces 340LS2 and 340US2. The second side surface 340LS2 or 340US2 of the chip mold layer 340 in one of the paired second semiconductor chips 300 may face the second side surface 340LS2 or 340US2 of the chip mold layer 340 in the other of the paired second semiconductor chips 300.

The second side surface 340LS2 or 340US2 of the chip mold layer 340 may have a staircase structure. The second upper side surface 340US2 of the chip mold layer 340 may be recessed from the second lower side surface 340LS2 of the chip mold layer 340 toward an inner portion of the chip mold layer 340. The second upper side surface 340US2 of the chip mold layer 340 in one of the paired second semiconductor chips 300 may face the second upper side surface 340US2 of the chip mold layer 340 in the other of the paired second semiconductor chips 300. The second lower side surface 340LS2 of the chip mold layer 340 in one of the paired second semiconductor chips 300 may face the second lower side surface 340LS2 of the chip mold layer 340 in the other of the paired second semiconductor chips 300. A third distance DS3 between the second upper side surfaces 340US2 of the chip mold layers 340 of the paired second semiconductor chips 300 may be larger than a fourth distance DS4 between the second lower side surfaces 340LS2 of the chip mold layers 340 of the paired second semiconductor chips 300.

Second bumps 350 may be disposed between each of the paired second semiconductor chips 300 and the upper substrate 100 and may be (e.g., electrically) connected to the buffer penetration electrodes 315. Each of the paired second semiconductor chips 300 may be electrically connected to the upper substrate 100 through the second bumps 350.

An upper under-fill layer 400 may be interposed between each of the paired second semiconductor chips 300 and the upper substrate 100 to fill a space between the second bumps 350. The upper under-fill layer 400 may be extended into a space between the paired second semiconductor chips 300. The upper under-fill layer 400 may be extended into a space between the second lower side surfaces 340LS2 of the chip mold layers 340 of the paired second semiconductor chips 300 and may expose the second upper side surfaces 340US2 of the chip mold layers 340 of the paired second semiconductor chips 300. The uppermost surface 400U of the upper under-fill layer 400 may be located at a height that is lower than the upper surfaces 300U of the paired second semiconductor chips 300.

An upper mold layer 500 may be disposed on the upper substrate 100 to cover side surfaces of the paired second semiconductor chips 300. The upper mold layer 500 may be extended into a space between the second upper side surfaces 340US2 of the chip mold layers 340 of the paired second semiconductor chips 300 and may cover the uppermost surface 400U of the upper under-fill layer 400. The upper mold layer 500 may fill a space between the second upper side surfaces 340US2 of the chip mold layers 340 of the paired second semiconductor chips 300 and to be in direct contact with the uppermost surface 400U of the upper under-fill layer 400. The upper surface 500U of the upper mold layer 500 may be located at the same height as the upper surfaces 300U of the paired second semiconductor chips 300. The upper surface 500U of the upper mold layer 500 may be coplanar with the upper surfaces 300U of the paired second semiconductor chips 300.

In the case where a distance between the paired second semiconductor chips 300 is relatively small, the upper under-fill layer 400 may be extended into a space between the paired second semiconductor chips 300 by the capillary force and may be extended at the same height as the upper surfaces 300U of the paired second semiconductor chips 300. Accordingly, the upper under-fill layer 400 may fill a space between the paired second semiconductor chips 300 and may be exposed to the outside of the semiconductor package 1200. In this case, a crack may occur between the paired second semiconductor chips 300, because the upper under-fill layer 400 has a relatively great thermal expansion coefficient, and such a crack may propagate into the semiconductor package 1200. In addition, a warpage failure may occur in the semiconductor package 1200.

According to an embodiment of the inventive concept, the chip mold layer 340 of each of the paired second semiconductor chips 300 may be partially removed from a region between the paired second semiconductor chips 300. Thus, the second upper side surface 340US2 of the chip mold layer 340 may be recessed from the second lower side surface 340LS2 of the chip mold layer 340 toward an inner portion of the chip mold layer 340. The second side surface 340LS2 or 340US2 of the chip mold layer 340 may have a staircase structure. The third distance DS3 between the second upper side surfaces 340US2 of the chip mold layers 340 of the paired second semiconductor chips 300 may be larger than the fourth distance DS4 between the second lower side surfaces 340LS2 of the chip mold layers 340 of the paired second semiconductor chips 300. In this case, the upper under-fill layer 400 may be extended into the relatively narrow space between the second lower side surfaces 340LS2 of the chip mold layers 340 of the paired second semiconductor chips 300 by the capillary force but might not be extended into the relatively wide space between the second upper side surfaces 340US2 of the chip mold layers 340 of the paired second semiconductor chips 300. The uppermost surface 400U of the upper under-fill layer 400 may be located at a height that is lower than the upper surfaces 300U of the paired second semiconductor chips 300. The upper mold layer 500 may fill a space between the second upper side surfaces 340US2 of the chip mold layers 340 of the paired second semiconductor chips 300 and may cover the uppermost surface 400U of the upper under-fill layer 400. The upper under-fill layer 400 might not be exposed to the outside of the semiconductor package 1200, because it is covered with the upper mold layer 500. Since the upper mold layer 500 has a thermal expansion coefficient that is less than the upper under-fill layer 400, a crack failure between the paired second semiconductor chips 300 may be reduced, and a warpage failure of the semiconductor package 1200 may also be reduced.

Since the crack and warpage issues are suppressed, it may be possible to realize a highly-reliable semiconductor package.

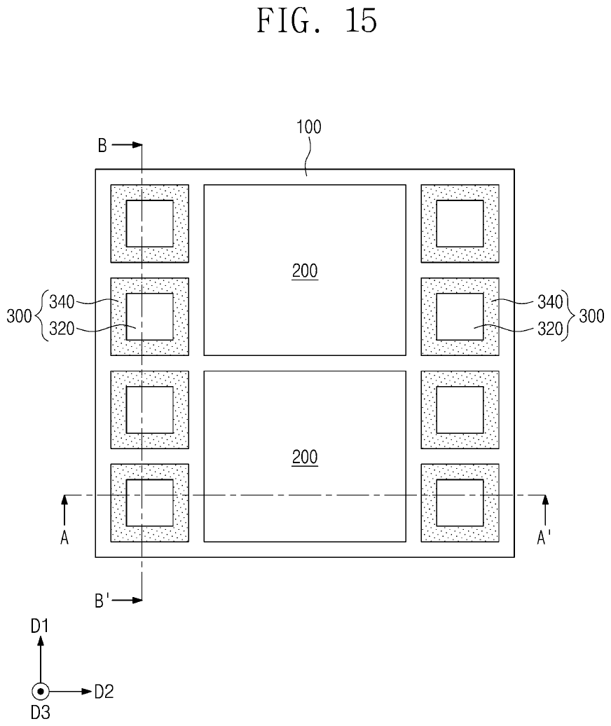

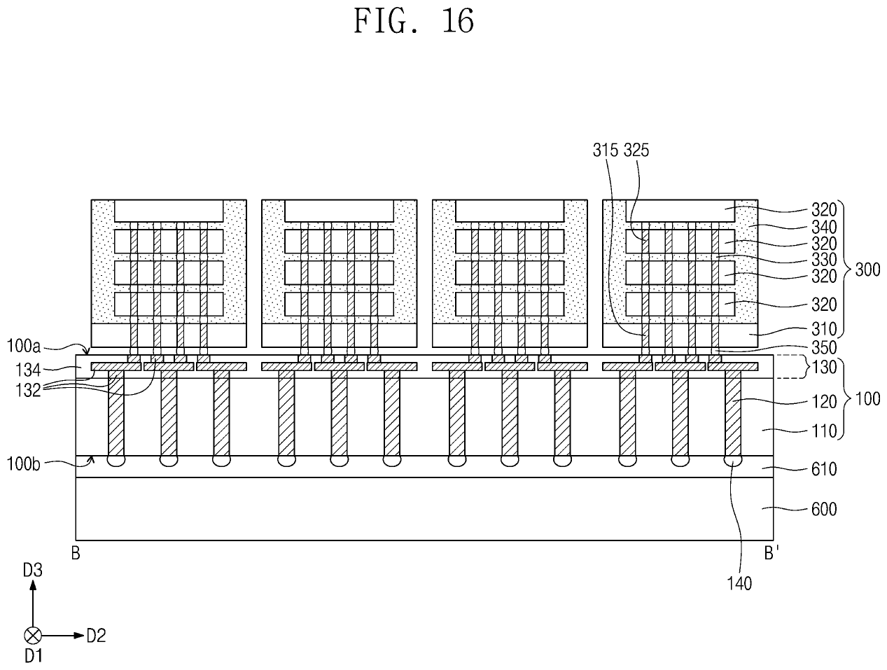

FIGS. 15, 17, 19, and 21 are plan views illustrating a method of fabricating a semiconductor package, according to an embodiment of the inventive concept. FIGS. 16, 18, 20, and 22 are cross-sectional views taken along lines B-B′ of FIGS. 15, 17, 19, and 21, respectively. Sectional views, which are taken along lines A-A′ of FIGS. 15, 17, 19, and 21, may be substantially the same as those illustrated in FIGS. 4, 6, 8, and 10, respectively. For concise description, features different from the fabrication method described with reference to FIGS. 3 to 10 will be mainly described below and to the extent that an element is not described in detail with respect to this figure, it may be understood that the element is at least similar to a corresponding element that has been described elsewhere within the present disclosure.

Referring to FIGS. 15 and 16, an upper substrate 100 may be disposed on a carrier substrate 600, and an adhesion layer 610 may be disposed between the carrier substrate 600 and the upper substrate 100. A first semiconductor chip 200 and a second semiconductor chip 300 may be mounted on the first surface 100a of the upper substrate 100.

In an embodiment, a plurality of first semiconductor chips 200 may be mounted on the first surface 100a of the upper substrate 100 and may be spaced apart from each other in the first direction D1. A plurality of second semiconductor chips 300 may be mounted on the first surface 100a of the upper substrate 100 and may be disposed at both sides of each of the first semiconductor chips 200. The second semiconductor chips 300 may form first and second columns, where the second semiconductor chips 300 in the first column are spaced apart from each other in the first direction D1 at one side of each of the first semiconductor chips 200 and the second semiconductor chips 300 in the second column are spaced apart from each other in the first direction D1 at an opposite side of each of the first semiconductor chips 200.

The second semiconductor chips 300 may include a pair of second semiconductor chips 300, which are most adjacent to each other in the first direction D1. Each of the paired second semiconductor chips 300 may include a buffer semiconductor chip 310, a plurality of sub-semiconductor chips 320 stacked on the buffer semiconductor chip 310 in the third direction D3, and a chip mold layer 340, which is disposed on the buffer semiconductor chip 310 to cover side surfaces of the sub-semiconductor chips 320. Each of the paired second semiconductor chips 300 may further include sub-bumps 330, which are disposed between the sub-semiconductor chips 320 and between the lowermost one of the sub-semiconductor chips 320 and the buffer semiconductor chip 310.

Second bumps 350 may be disposed between each of the paired second semiconductor chips 300 and the upper substrate 100, and may be (e.g., electrically) connected to the buffer penetration electrodes 315. Each of the paired second semiconductor chips 300 may be electrically connected to the upper substrate 100 through the second bumps 350.

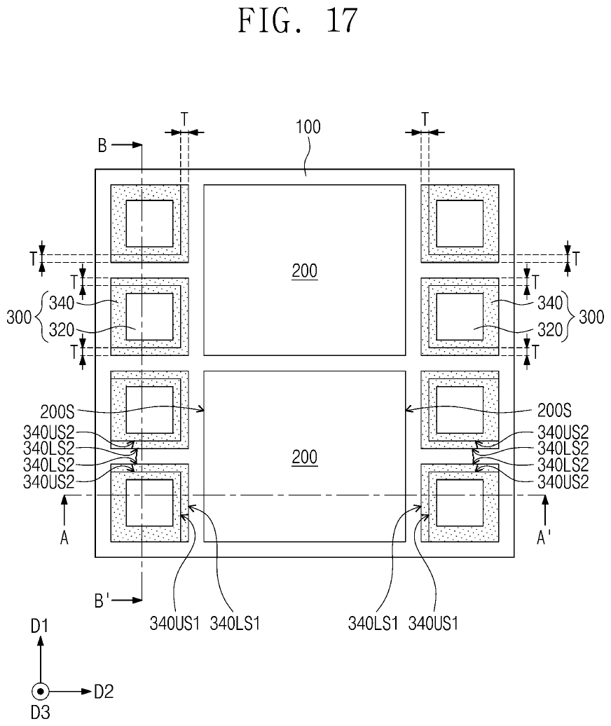

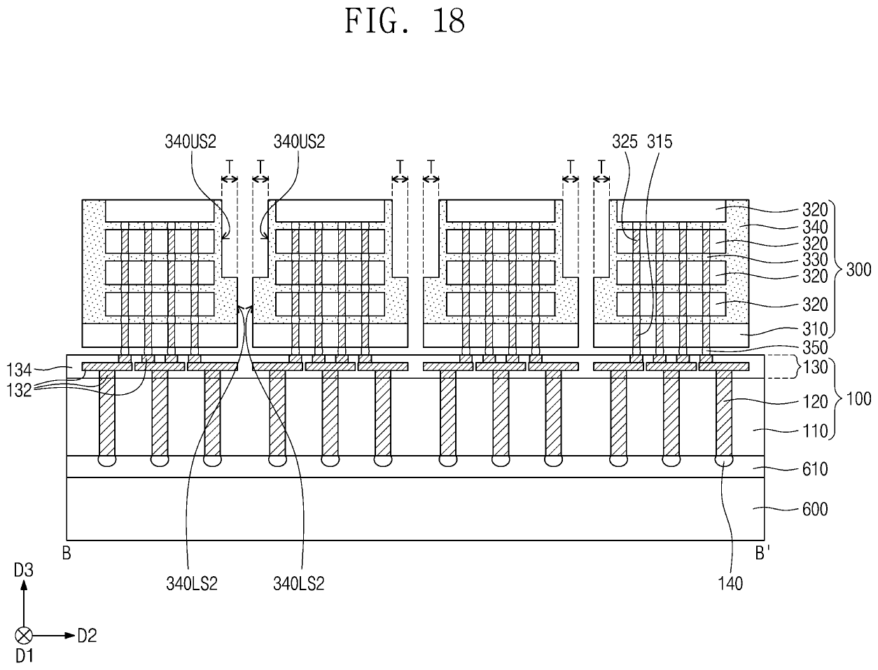

Referring to FIGS. 17 and 18, a portion of the chip mold layer 340 of each of the paired second semiconductor chips 300 may be removed from a region between each of the paired second semiconductor chips 300 and the first semiconductor chip 200. In addition, another portion of the chip mold layer 340 of each of the paired second semiconductor chips 300 may be removed from a region between the paired second semiconductor chips 300. The partial removal of the chip mold layer 340 may be performed using, for example, a laser process. Since the portions of the chip mold layer 340 are removed, a trench T may be formed in the chip mold layer 340. The trench T may penetrate a portion of the chip mold layer 340 and to extend in the first and second directions D1 and D2.

The chip mold layer 340 may have a first upper side surface 340US1, a first lower side surface 340LS1, a second upper side surface 340US2, and a second lower side surface 340LS2 that are defined by the trench T. The first upper side surface 340US1 of the chip mold layer 340 may be recessed from the first lower side surface 340LS1 of the chip mold layer 340 toward an inner portion of the chip mold layer 340, and thus, the first side surface 340LS1 or 340US1 of the chip mold layer 340 may have a staircase structure. The first upper side surface 340US1 and the first lower side surface 340LS1 of the chip mold layer 340 may correspond to the upper side surface 340US and the lower side surface 340LS of the chip mold layer 340 described with reference to FIG. 6. The second upper side surface 340US2 of the chip mold layer 340 may be recessed from the second lower side surface 340LS2 of the chip mold layer 340 toward an inner portion of the chip mold layer 340, and thus, the second side surface 340LS2 or 340US2 of the chip mold layer 340 may have a staircase structure.

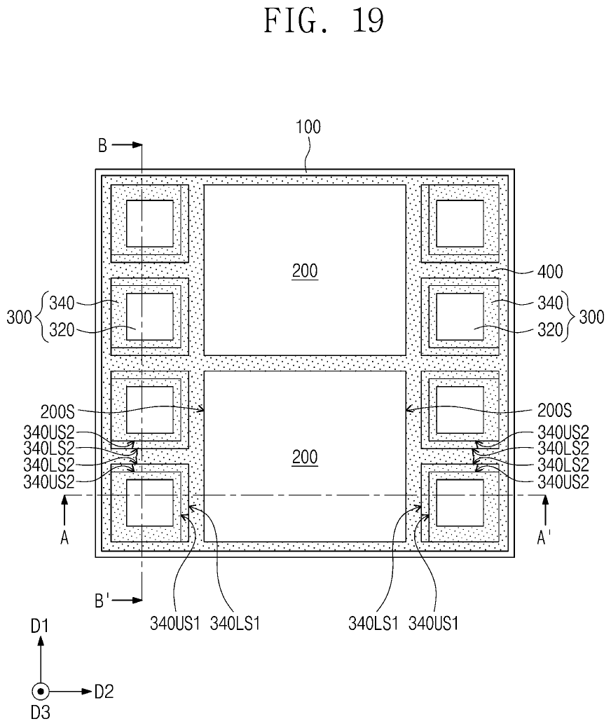

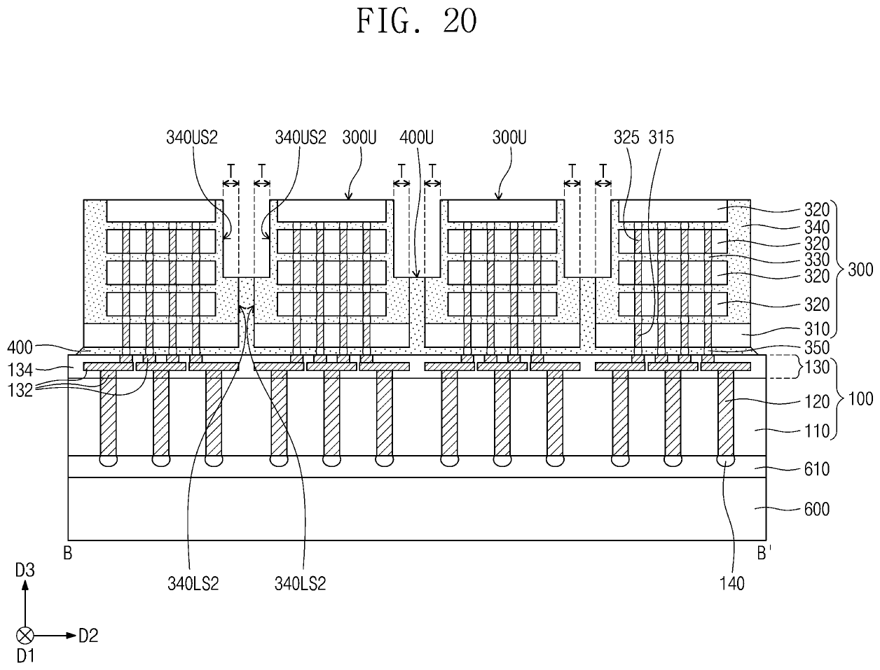

Referring to FIGS. 19 and 20, an upper under-fill layer 400 may be formed between each of the paired second semiconductor chips 300 and the upper substrate 100. The upper under-fill layer 400 may fill a space between the second bumps 350. The upper under-fill layer 400 may be extended into a space between the paired second semiconductor chips 300 by the capillary force. The upper under-fill layer 400 may be extended into a space between the second lower side surfaces 340LS2 of the chip mold layers 340 of the paired second semiconductor chips 300.

Owing to the trench T, a space between the second upper side surfaces 340US2 of the chip mold layers 340 of the paired second semiconductor chips 300 may be larger than a space between the second lower side surfaces 340LS2 of the chip mold layers 340 of the paired second semiconductor chips 300. Thus, the upper under-fill layer 400 might not be extended into a space between the second upper side surfaces 340US2 of the chip mold layers 340 of the paired second semiconductor chips 300. The uppermost surface 400U of the upper under-fill layer 400 may be located at a height that is lower than the upper surfaces 300U of the paired second semiconductor chips 300.

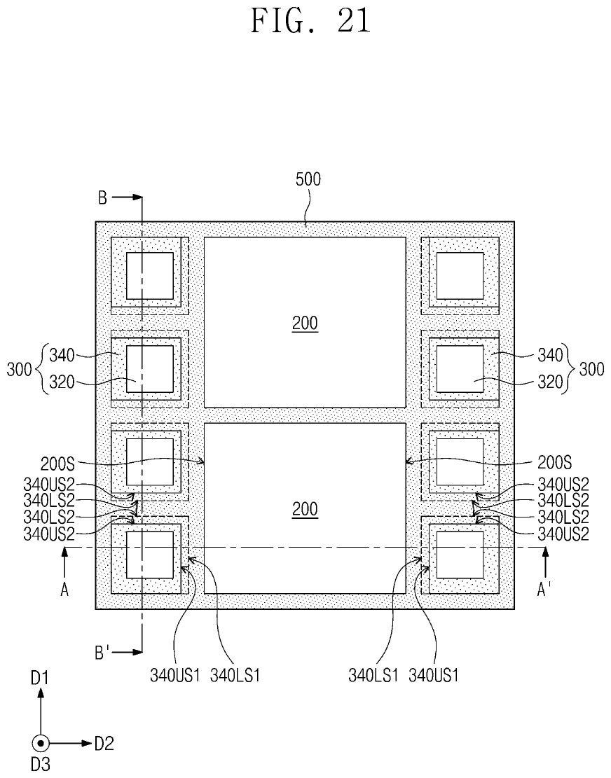

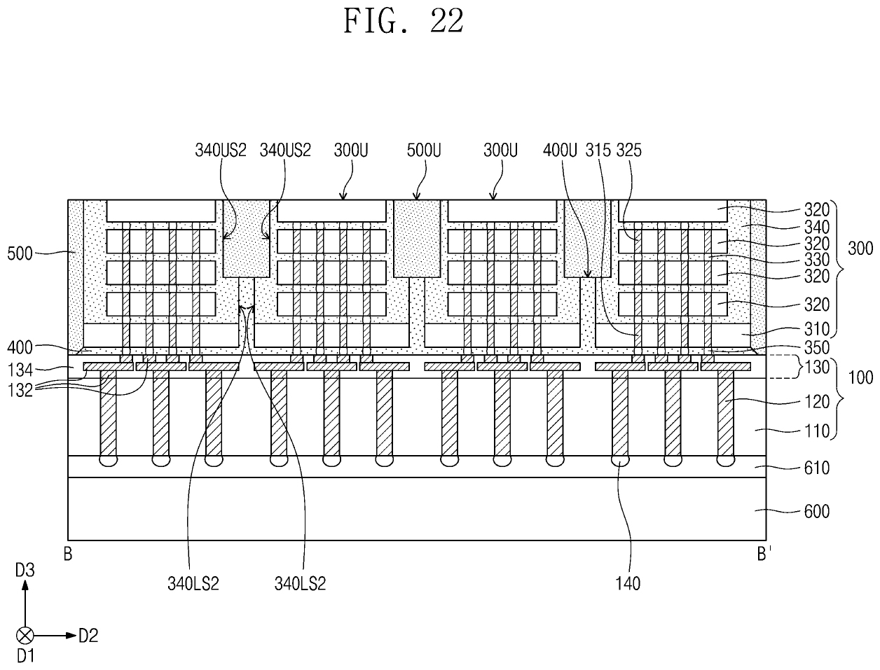

Referring to FIGS. 21 and 22, an upper mold layer 500 may be formed on the upper substrate 100 to cover side surfaces of the paired second semiconductor chips 300. The upper mold layer 500 may be extended into a space between the second upper side surfaces 340US2 of the chip mold layers 340 of the paired second semiconductor chips 300 and may cover the uppermost surface 400U of the upper under-fill layer 400. The formation of the upper mold layer 500 may include forming the upper mold layer 500 to cover the paired second semiconductor chips 300 and grinding the upper mold layer 500 to expose the upper surfaces 300U of the paired second semiconductor chips 300. As a result of the grinding process, the upper surface 500U of the upper mold layer 500 may be located at the same height as the upper surfaces 300U of the paired second semiconductor chips 300.

Referring back to FIGS. 13 and 14, the carrier substrate 600 and the adhesion layer 610 may be removed from the upper substrate 100, and the connection terminals 140 may be exposed. Thus, the semiconductor package 1200, according to an embodiment of the inventive concept, may be formed.

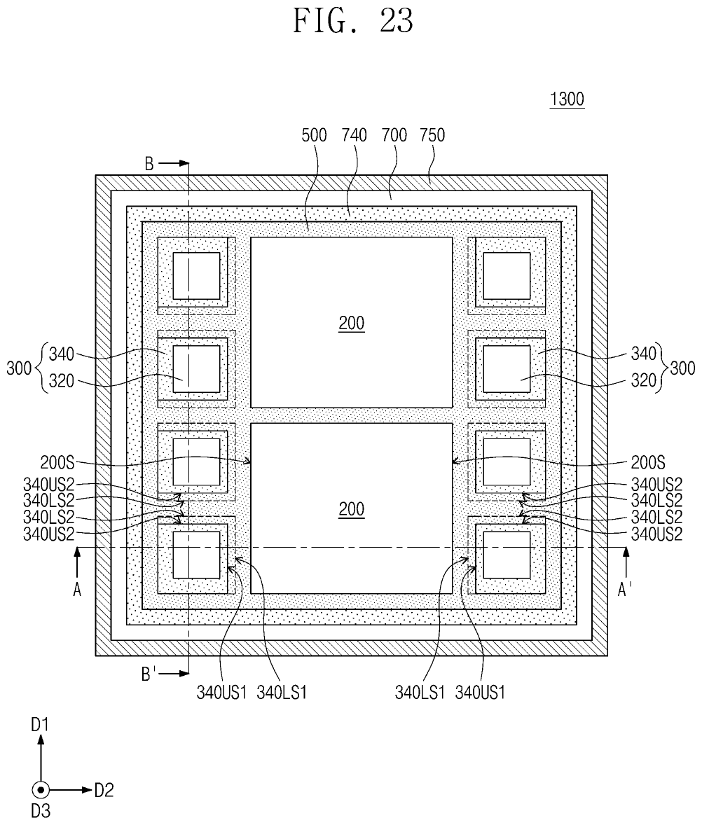

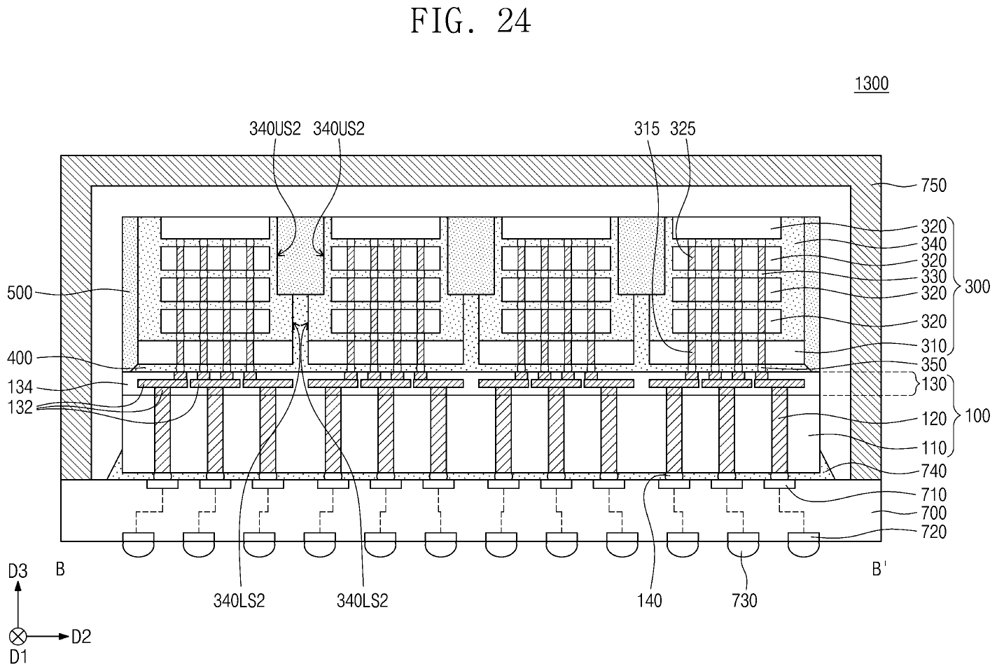

FIG. 23 is a plan view illustrating a semiconductor package according to an embodiment of the inventive concept. FIG. 24 is a cross-sectional view taken along a line B-B′ of FIG. 23. The sectional view taken along a line A-A′ of FIG. 23 may be the same as FIG. 12A. For concise description, features different from the semiconductor package previously described with reference to FIGS. 11, 12A, and 12B will be mainly described below and to the extent that an element is not described in detail with respect to this figure, it may be understood that the element is at least similar to a corresponding element that has been described elsewhere within the present disclosure.

Referring to FIGS. 23 and 24, a semiconductor package 1300 may include a lower substrate 700 and a heat-dissipation structure 750, which is disposed on the lower substrate 700. The semiconductor package 1200 described with reference to FIGS. 13 and 14 may be mounted on the lower substrate 700 and may be disposed in the heat-dissipation structure 750.

The lower substrate 700 may include first substrate pads 710, which are adjacent to the upper surface 700U of the lower substrate 700, and second substrate pads 720, which are adjacent to the lower surface 700L of the lower substrate 700. In an embodiment, the lower substrate 700 may be a printed circuit board (PCB). Outer terminals 730 may be disposed on the lower surface 700L of the lower substrate 700 and may be connected to the second substrate pads 720, respectively.

Connection terminals 140 may be disposed between the upper substrate 100 and the lower substrate 700 and may be connected (e.g., electrically) to the first substrate pads 710 of the lower substrate 700, respectively. The upper substrate 100 may be electrically connected to the lower substrate 700 through the connection terminals 140. A lower under-fill layer 740 may be interposed between the upper substrate 100 and the lower substrate 700 to fill a space between the connection terminals 140.

The heat-dissipation structure 750 may have substantially the same features as the heat-dissipation structure 750 described with reference to FIGS. 11 and 12A. In an embodiment, the stiffener 760 described with reference to FIGS. 11 and 12B may be disposed on the lower substrate 700, and the semiconductor package 1200 described with reference to FIGS. 13 and 14 may be disposed in the stiffener 760.

According to an embodiment of the inventive concept, a chip mold layer of a second semiconductor chip may be partially removed, and thus, an upper side surface of the chip mold layer may be recessed from a lower side surface of the chip mold layer toward an inner portion of the chip mold layer. A first distance between the upper side surface of the chip mold layer and an upper side surface of a first semiconductor chip may be larger than a second distance between the lower side surface of the chip mold layer and a lower side surface of the first semiconductor chip. In this case, an upper under-fill layer may be extended into a relatively small space between the lower side surface of the chip mold layer and the lower side surface of the first semiconductor chip by the capillary force but might not be extended into a relatively large space between the upper side surface of the chip mold layer and the upper side surface of the first semiconductor chip. An upper mold layer may fill a space between the upper side surface of the chip mold layer and the upper side surface of the first semiconductor chip and may cover the uppermost surface of the upper under-fill layer. The upper under-fill layer might not be exposed to the outside of the semiconductor package, because it is covered with the upper mold layer. Since the upper mold layer has a thermal expansion coefficient smaller than the upper under-fill layer, it may be possible to suppress crack and warpage issues in the semiconductor package.

Since the crack and warpage issues are suppressed, it may be possible to realize a highly reliable semiconductor package and a fabrication method thereof.

While example embodiments of the inventive concept have been particularly shown and described, it will be understood by one of ordinary skill in the art that variations in form and detail may be made therein without departing from the spirit and scope of the present disclosure.

1. A semiconductor package, comprising:
a first semiconductor chip and a second semiconductor chip disposed on an upper substrate and horizontally spaced apart from each other;
an upper under-fill layer interposed between the upper substrate and the first semiconductor chip and interposed between the upper substrate and the second semiconductor chip; and
an upper mold layer disposed on the upper substrate and covering side surfaces of the first and second semiconductor chips,
wherein the second semiconductor chip comprises:
sub-semiconductor chips stacked in a vertical direction perpendicular to an upper surface of the upper substrate; and
a chip mold layer covering side surfaces of the sub-semiconductor chips,
wherein the upper under-fill layer is extended into a space between a lower side surface of the chip mold layer and a lower side surface of the first semiconductor chip,
wherein the upper mold layer is extended into a space between an upper side surface of the chip mold layer and an upper side surface of the first semiconductor chip and covers the uppermost surface of the upper under-fill layer, and
wherein the upper side surface of the chip mold layer is recessed from the lower side surface of the chip mold layer toward an inner portion of the chip mold layer.

2. The semiconductor package of claim 1, wherein a first distance between the upper side surface of the chip mold layer and the upper side surface of the first semiconductor chip is larger than a second distance between the lower side surface of the chip mold layer and the lower side surface of the first semiconductor chip.

3. The semiconductor package of claim 2, wherein the upper side surface of the first semiconductor chip and the lower side surface of the first semiconductor chip are aligned with each other in the vertical direction.

4. The semiconductor package of claim 1, wherein a thermal expansion coefficient of the upper mold layer is smaller than a thermal expansion coefficient of the upper under-fill layer.

5. The semiconductor package of claim 1, wherein a mass of fillers in the upper mold layer is greater than a mass of fillers in the upper under-fill layer.

6. The semiconductor package of claim 1, wherein a volume of a filler in the upper mold layer is larger than a volume of a filler in the upper under-fill layer.

7. The semiconductor package of claim 1, wherein the upper substrate has a first surface and a second surface, which are opposite to each other,
wherein the upper substrate comprises:
an interconnection layer adjacent to the first surface, the interconnection layer comprising interconnection patterns;
a semiconductor substrate adjacent to the second surface; and
a plurality of penetration electrodes penetrating the semiconductor substrate and connected to corresponding ones of the interconnection patterns, and
wherein the first and second semiconductor chips are disposed on the first surface of the upper substrate and are connected to corresponding ones of the interconnection patterns in the interconnection layer.

8. The semiconductor package of claim 7, further comprising connection terminals disposed on the second surface of the upper substrate and connected to the penetration electrodes.

9. The semiconductor package of claim 8, further comprising a lower substrate that is spaced apart from the second surface of the upper substrate with the connection terminals interposed therebetween,
wherein the upper substrate is electrically connected to the lower substrate through the connection terminals.

10. The semiconductor package of claim 1, wherein the first semiconductor chip and the second semiconductor chip are two different semiconductor chips that are selected from a memory chip, a logic chip, an application processor (AP) chip, and a system-on-chip (SOC).

11. A semiconductor package, comprising:
a first semiconductor chip and a second semiconductor chip disposed on an upper substrate and horizontally spaced apart from each other;
an upper under-fill layer interposed between the upper substrate and the first semiconductor chip and interposed between the upper substrate and the second semiconductor chip; and
an upper mold layer interposed between the first semiconductor chip and the second semiconductor chip,
wherein the second semiconductor chip comprises:
at least one sub-semiconductor chip; and
a chip mold layer covering a side surface of the at least one sub-semiconductor chip,
wherein a lower side surface of the chip mold layer faces a lower side surface of the first semiconductor chip,
wherein an upper side surface of the chip mold layer faces an upper side surface of the first semiconductor chip,
wherein the upper side surface of the chip mold layer is recessed from the lower side surface of the chip mold layer toward an inner portion of the chip mold layer,
wherein the upper under-fill layer is extended into a space between the lower side surface of the chip mold layer and the lower side surface of the first semiconductor chip,
wherein the uppermost surface of the upper under-fill layer is located at a height that is lower than upper surfaces of the first and second semiconductor chips, and
wherein the upper mold layer fills a space between the upper side surface of the chip mold layer and the upper side surface of the first semiconductor chip and covers the uppermost surface of the upper under-fill layer.

12. The semiconductor package of claim 11, wherein a first distance between the upper side surface of the chip mold layer and the upper side surface of the first semiconductor chip is larger than a second distance between the lower side surface of the chip mold layer and the lower side surface of the first semiconductor chip.

13. The semiconductor package of claim 11, wherein the upper under-fill layer exposes the upper side surface of the chip mold layer and the upper side surface of the first semiconductor chip.

14. The semiconductor package of claim 11, wherein the upper side surface of the first semiconductor chip and the lower side surface of the first semiconductor chip are aligned with each other in a vertical direction perpendicular to an upper surface of the upper substrate.

15. The semiconductor package of claim 11, wherein a thermal expansion coefficient of the upper mold layer is lower than a thermal expansion coefficient of the upper under-fill layer.

16. The semiconductor package of claim 11, wherein a mass of fillers in the upper mold layer is greater than a mass of fillers in the upper under-fill layer.

17. The semiconductor package of claim 11, wherein each of the upper mold layer and the chip mold layer comprises an epoxy molding compound.

18. The semiconductor package of claim 11, wherein the upper substrate is an interposer substrate, and
wherein the first semiconductor chip and the second semiconductor chip are two different semiconductor chips that are selected from a memory chip, a logic chip, an application processor (AP) chip, and a system-on-chip (SOC).

19. The semiconductor package of claim 18, wherein the second semiconductor chip comprises a plurality of sub-semiconductor chips stacked in a vertical direction perpendicular to an upper surface of the upper substrate, and
wherein the chip mold layer covers side surfaces of the sub-semiconductor chips.

20. The semiconductor package of claim 1, wherein the upper substrate has a first surface and a second surface, which are opposite to each other,
wherein the upper substrate comprises:
an interconnection layer adjacent to the first surface, the interconnection layer comprising interconnection patterns;
a semiconductor substrate adjacent to the second surface; and
a plurality of penetration electrodes penetrating the semiconductor substrate and connected to corresponding ones of the interconnection patterns,
wherein the first and second semiconductor chips are disposed on the first surface of the upper substrate and are electrically connected to corresponding ones of the interconnection patterns in the interconnection layer.

21-25. (canceled)
